(19) United States
(12) Patent Application Publication
(10) Pub. No.: US 2005/0104822 A1
(43) Pub. Date: May 19, 2005

(54) Self light emission display device

(75) Inventor: Shuichi Seki, Yonezawa-shi (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: TOHOKU PIONEER CORPORATION, Tendo-shi (JP)

(21) Appl. No.: 10/951,799

(22) Filed: Sep. 29, 2004

(30) Foreign Application Priority Data
Nov. 13, 2003 (JP) 2003-383258

(51) Int. Cl. G09G 3/32

(52) U.S. Cl. 345/82

(57) ABSTRACT

A self light emission display device which substantially enables dual scan drive by one data driver comprises a plurality of scan lines K1, K2, . . . which are arranged in a horizontal direction, a plurality of data lines A1, A2, . . . which intersect these scan lines and are arranged in a vertical direction, and a plurality of light emitting elements Ra11, Rb11, . . . arranged on intersecting areas of the scan lines and the data lines. Cathode terminals of the light emitting elements whose anode terminals are connected respectively to the two adjacent data lines A1, A2 are connected to different scan lines one by one. Any two of the scan lines are selected for scanning simultaneously. Thus, since light emission duty of each EL element can also be approximately doubled, instantaneous light emission intensity of each EL element can be set low, and stress on the EL elements can be reduced. Further, since respective data lines can be drawn from one side end portion of the display panel, dual scan drive becomes substantially possible by one data driver.

### BACKGROUND OF THE INVENTION

1. Field of the Invention

The present invention relates to a self light emission display device aimed at a passive matrix type display panel in which for example organic EL (electroluminescent) elements are employed as light emitting elements, and particularly to a self light emission display device which is suitable for forming a large size display panel.

2. Description of the Related Art

A display panel constructed by arranging light emitting elements in a matrix pattern has been developed widely, and as the light emitting element employed in such a display panel, an organic EL element in which an organic material is employed in the light emitting layer thereof has attracted attention. This is because of backgrounds one of which is that by employing, in the light emitting layer of the element, an organic compound which enables an excellent light emission characteristic to be expected, a high efficiency and a long life which can be equal to practical use have been advanced.

The organic EL element electrically can be replaced by a structure composed of a light emitting component having a diode characteristic and a parasitic capacitance component which is connected in parallel to this light emitting component, and the organic EL element can be said to be a capacitive light emitting element. Regarding the organic EL element, due to reasons that the voltage-intensity characteristic thereof is unstable with respect to temperature changes while the current-intensity characteristic thereof is stable with respect to temperature changes and that degradation of the organic EL element is considerable when the organic EL element receives excess current so that the light emission lifetime is shortened, and the like, a constant current drive is performed generally. As a display panel employing such organic EL elements, a passive drive type display panel in which elements are arranged in a matrix pattern has already been put into practical use partly.

FIG. 1 shows a conventional passive matrix type display panel and basic structures of drive circuits therefor. Regarding this passive matrix drive system, as drive methods for organic EL elements there are two methods that are cathode line scan/anode line drive and anode line scan/cathode line drive, and the structure shown in FIG. 1 shows a form of the former cathode line scan/anode line drive. That is, anode lines A1-An as n drive lines are arranged in a vertical direction, cathode lines K1-Km as m scan lines are arranged in a horizontal direction, and organic EL elements E11-Enm designated by symbols/marks of diodes are arranged at respective intersecting portions (in total, n×m portions) to construct a display panel 1.

In the respective EL elements E11-Enm constituting pixels, one ends thereof (anode terminals in equivalent diodes of EL elements) are connected to the anode lines and the other ends thereof (cathode terminals in equivalent diodes of EL elements) are connected to the cathode lines, corresponding to respective intersection positions between the anode lines A1-An extending along the vertical direction and the cathode lines K1-Km extending along the horizontal direction. Further, one end portions of the respective anode lines A1-An are respectively connected to a data driver 2, and one end portions of the respective cathode lines K1-Km are connected to a scan driver 3 so as to be driven respectively.

The scan driver 3 selects and scans the cathode lines K1-Km which are connected to the scan driver 3 by alternatively connecting the cathode lines K1-Km for example with a reference potential point (ground) one after another, and the data driver 2 operates to selectively make pixels emit light by appropriately supplying light emission drive current to the respective anode lines A1-An, in synchronization with said selective scanning.

Meanwhile, with a display panel by this type of passive matrix drive system, as the panel size is made larger, the number of scan lines can also be increased. However, in the case where the number of scan lines is increased, the time in which one scan line is scanned is shortened approximately proportionally to the increase, and therefore the time during which the EL element emits light (light emission duty) is also shortened. Thus, means for ensuring brightness of a display screen by making an instantaneous intensity at which the element emits light momentarily higher has to be adopted.

In this manner, it is necessary to increase light emission drive current in order to increase the instantaneous intensity of the light emitting element, and accompanied by this it is desired that an IC which performs drive control is capable of withstanding a high voltage, whereby problems occur in terms of technology and cost. In addition to this, an increase in the light emission drive current incurs a result that the light emission lifetime of the element is shortened.

Thus, in a case where a display panel is large-sized as described above which influences the light emission lifetime of the element considerably, means for dividing scans of one display panel into two and displaying them may be adopted. This method is generally called a dual scan drive method, and a dual scan drive method aimed at for example a liquid crystal display panel is disclosed in Japanese Patent Application Laid-Open No. 2001-356744 shown below.

FIG. 2 shows an example in which the dual scan drive method is adopted and shows an example of a case where 120 pixels are formed in one scan line and where 160 scan lines are arranged. In the structure shown in FIG. 2, anode lines as data lines are divided into two sections, the upper and lower, and in the upper side display panel 1A, the anode lines are connected to a data driver A designated by reference character 2A to be driven to be lit. In the lower side display panel 1B, the anode lines are connected to a data driver B designated by reference character 2B to be driven to be lit.

Meanwhile, a scan driver 3 operates to sequentially scan 80 cathode lines in the display panel 1A of the upper side and at the same time to sequentially scan 80 cathode lines in the display panel 1B of the lower side. In synchronization with this scan, the light emission drive current is selectively supplied from the data driver A and the data driver B to the anode lines arranged in the respective display panels 1A, 1B, so that a predetermined image can be displayed treating the upper and lower side display panels 1A, 1B as one display device.

In the case where this dual scan drive method is adopted, according to the above-described example, since 160 scan lines are divided into two sections, the upper and lower, so that the respective sections can be driven, for example one frame period can be constituted by 80 scans. Thus, since one scan time can be taken long, brightness of the screen can be ensured without making the instantaneous intensity of the element. Thus, the drive current for the elements which has been considered as a technical problem in the case where the passive drive method is adopted can be reduced, and the light emission lifetime can be prolonged to some degree.

Meanwhile, in the case where the dual scan drive system for the upper and lower sections is adopted as described above, the data driver A for driving the upper side display panel 1A and the data driver B for driving the lower side display panel 1B are needed, and these two data drivers have to physically sandwich the light emission image area, being arranged at two sides thereof. Thus, it becomes difficult to make the data drivers into one chip, and a problem remains in terms of the cost.

With respect to the scan driver 3, since the upper and lower display panels 1A, 1B are scanned respectively and independently, basically two scan drivers are needed. As the structure shown in FIG. 2, by arranging the scan drivers at one end side (the left end side in FIG. 2) of the upper and lower display panels 1A, 1B, it is possible to make them into one chip, however.

In the case where the dual scan drive system is adopted as described above, although the light emission duty of the element can be large, since it is necessary to dispose two data drivers independently, a problem remains in terms of the cost. Even in a case where a display screen is to be further large-sized by connecting display panels, limitations occur physically in terms of arrangement and structure of the data drivers.

### SUMMARY OF THE INVENTION

The present invention has been developed as attention to the above-described problems has been paid, and it is an object of the present invention to provide a self light emission display device in which the light emission duty of the element can be ensured similarly to the conventional dual scan drive system and in which the dual scan drive is possible substantially by one data driver.

A self light emission display device according to the present invention which has been developed in order to solve the above-described problems is a display device having a plurality of scan lines arranged in one direction, a plurality of data lines arranged as intersecting the scan lines, and a plurality of light emitting elements arranged on intersecting areas of the scan lines and the data lines, characterized by being constructed in such a manner that while adjacent plural data lines are grouped, respective one terminals of the light emitting elements whose respective other terminals are connected to the grouped respective data lines are connected to different scan lines one by one so that any two of the scan lines are simultaneously selected for scanning.

### BRIEF DESCRIPTION OF THE DRAWINGS

FIG. 1 is a connection diagram showing an example of a conventional display panel and drive circuit thereof;

FIG. 2 is a schematic view showing an example in which the display panel shown in FIG. 1 is utilized and a dual scan drive system is adopted;

FIG. 3 is a connection diagram showing a display device according to the present invention;

FIG. 4 is a schematic view showing a lamination state of respective functional layers constituting the display panel shown in FIG. 3;

FIG. 5 is a schematic view explaining a scan state of the display panel shown in FIG. 3;

FIG. 6 is a schematic view showing a first example of a case where a display screen is large-sized utilizing the basic structure shown in FIG. 5;

FIG. 7 is a schematic view showing a second example of a case where a display screen is large-sized similarly;

FIG. 8 is a schematic view showing a third example of a case where a display screen is large-sized similarly;

FIG. 9 is a schematic view showing another example of a display panel which can be adopted suitably to a display device according to the present invention; and

FIG. 10 is a schematic view showing further another example of a display panel which can be adopted suitably to a display device according to the present invention.

### DESCRIPTION OF THE PREFERRED EMBODIMENTS

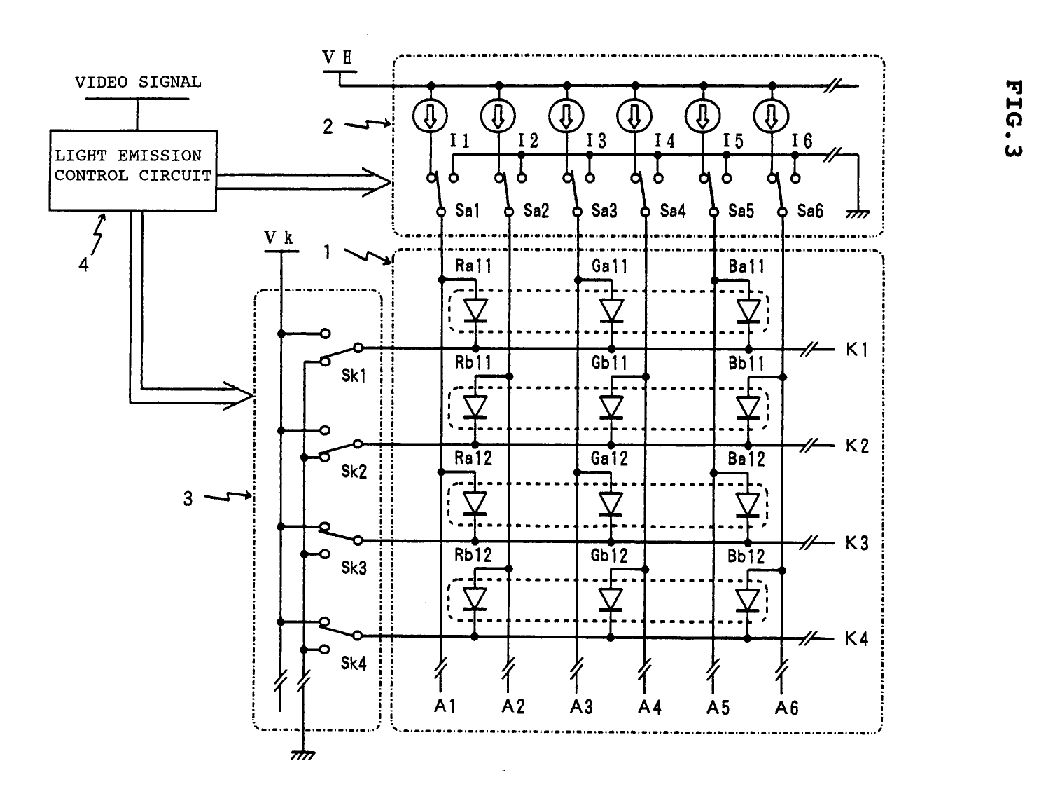

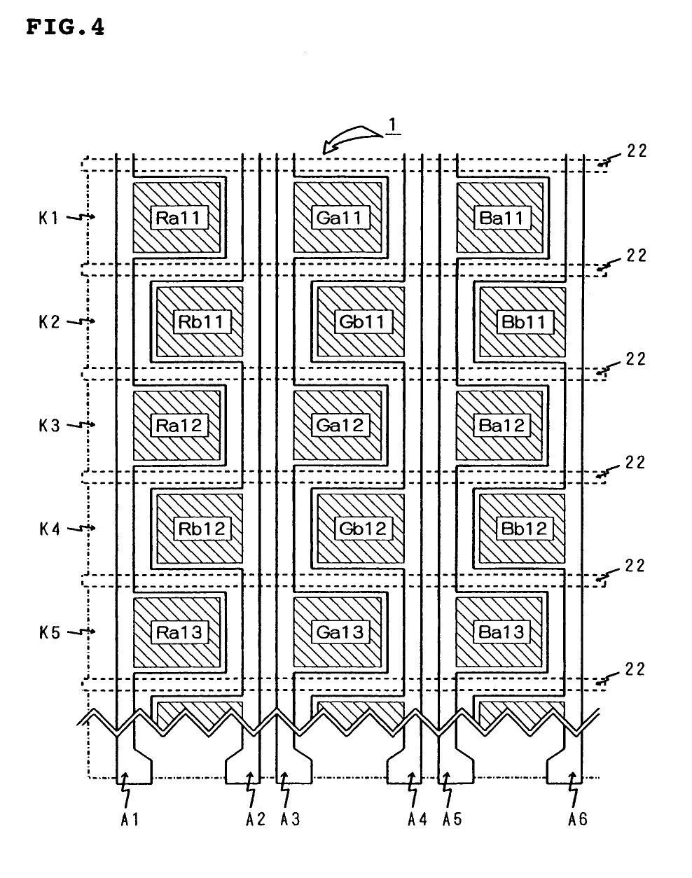

A self light emission display device according to the present invention will be described below with reference to an embodiment shown in FIGS. 3 and 4. First, FIG. 3 shows structures of a passive matrix type display panel and drive circuits therefor according to the present invention, and a display panel 1 shown in this FIG. 3 shows a form of a cathode line scan/anode line drive. Shown is a structure in which one pixel is formed while three subpixels that emit respective R (red), G (green), and B (blue) colors of light are grouped as surrounded by the broken line.

In the display panel 1 shown in FIG. 3, anode lines as data lines are arranged in a column (vertical) direction, and cathode lines as scan lines are arranged in a row (horizontal) direction. With respect to two adjacent anode lines, for example anode lines A1, A2, the anode terminal of an EL element Ra11 of red color light emission which is designated by the symbol of a diode is connected to one side anode line A1, and the cathode terminal thereof is connected to a first cathode line K1. The anode terminal of an EL element Rb11 of red color light emission that is the same color as Ra11 is connected to the other side anode line A2, and the cathode terminal thereof is connected to a second cathode line K2.

That is, this embodiment is constructed in such a manner that while two adjacent data lines are paired, one terminals (anode terminals) of the EL elements Ra11, Rb11 are connected to the paired data lines A1, A2, respectively, and the other terminals (cathode terminals) of the EL elements Ra11, Rb11 are connected to different scan lines K1, K2, respectively, one by one.

Similarly, with respect to two adjacent anode lines A1, A2 which are paired, the cathode terminal of the EL element Ra12 of red color light emission whose anode terminal is connected to the one side anode line A1 is connected to third cathode line K3, and the cathode terminal of the EL element Rb12 of red color light emission whose anode terminal is connected to the other side anode line A2 is connected to fourth cathode line K4. This connection form is constructed similarly also in fifth and following cathode lines though not shown in the drawing.

The connection form for EL elements as described above is similarly constructed also in two adjacent anode lines A3, A4 which are paired further, and EL elements Ga11, Gb11 . . . of green color light emission are connected to anode lines which form this pair. This connection form is similarly constructed also in two adjacent anode lines A5, A6 which are paired further, and EL elements Ba11, Bb11 . . . of blue color light emission are similarly connected to anode lines which form this pair. These connection forms are similarly constructed also for respective anode lines which are further arranged in a right side of the display panel 1 in FIG. 3 though not shown in the drawing.

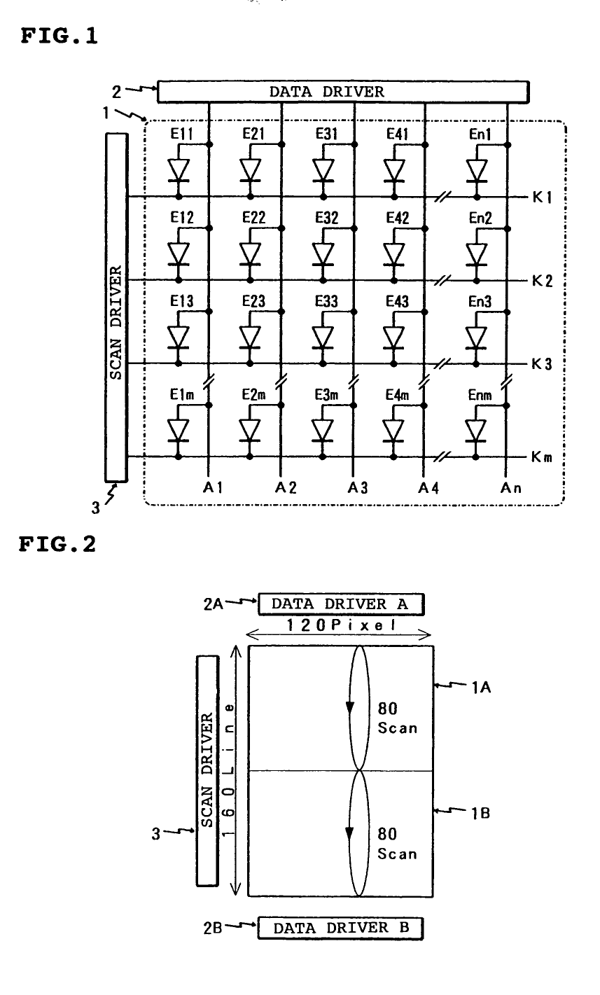

In the display panel 1 shown in this FIG. 3, when numbers K1, K2, . . . are assigned in a vertical direction from the top to the bottom one by one to cathode lines arranged in the row direction, and when cathode lines corresponding to numerals of odd numbers are set as odd number lines and cathode lines corresponding to numerals of even numbers are set as even number lines, the cathode terminals of the light emitting elements whose anode terminals are respectively connected to the paired, two adjacent anode lines are connected to the odd number lines and even number lines of the cathode lines alternately. In other words, the display panel 1 shown in FIG. 3 is constructed in such a manner that one anode line in the conventional display panel shown in FIG. 1 is divided into two.

One end portions of the respective anode lines are respectively connected to a data driver 2, and one end portions of the respective cathode lines are connected to a scan driver 3 so that the anode and cathode lines are driven respectively. The data driver 2 is provided with constant current sources I1, I2, . . . which utilize a drive voltage VH supplied to the data driver 2 to be operated and drive switches Sa1, Sa2 . . . , and the drive switches Sa1, Sa2 . . . are connected to the constant current sources I1, I2, . . . side so that current from the respective constant current sources is supplied to the respective EL elements arranged corresponding to cathode lines as drive current. When current from the constant current sources I1, I2, . . . is not supplied to the respective EL elements, the drive switches Sa1, Sa2 . . . can allow these anode lines to be connected to a ground side provided as a reference potential point.

Meanwhile, the scan driver 3 is equipped with scan switches Sk1, Sk2, . . . corresponding to the respective cathode lines K1, K2, . . . , and these scan switches operate to allow either a reverse bias voltage Vk constituted by a direct current voltage value for mainly preventing cross talk light emission or the ground potential provided as the reference potential point to be connected to a corresponding cathode line. In this case, any two of the cathode lines are simultaneously connected to the ground side which is provided as the reference potential point so that selective scanning is performed. FIG. 3 shows a state in which one (the cathode line K1) of the odd-numbered lines and one (the cathode line K2) of the even-numbered lines are simultaneously connected to the ground side which is provided as the reference potential point.

The state shown in FIG. 3 shows a case where the first and second cathode lines K1, K2 are connected to the ground side so as to be in a scan state, and at this time the respective drive switches Sa1, Sa2, . . . in the data driver 2 are appropriately connected to the constant current sources I1, I2, . . . side so that drive current is supplied to respective EL elements whose cathode electrodes are connected to the first and second cathode lines, whereby the EL elements in question can be driven to emit light.

A control bus is connected from a light emission control circuit 4 including a CPU to the data driver 2 and the scan driver 3, and switching operations of the scan switches Sk1, Sk2, . . . and the drive switches Sa1, Sa2, . . . are performed based on a video signal to be displayed. Thus, the constant current sources I1, I2, . . . are connected to desired anode lines while scan lines are set to the ground potential at a predetermined cycle based on the video signal as described above, and the respective EL elements are selectively illuminated so that an image based on the video signal is displayed on the display panel 1.

Thus, with a combination of the display panel 1 of the above-described structure and a cathode line scan means for simultaneously selecting and scanning any two of scan lines arranged in this display panel, selective scanning time of the respective cathode lines can be approximately doubled. Accordingly, since the light emission duty of each EL element can also be approximately doubled, the instantaneous light emission intensity of each EL element can be set low, and stress on the EL elements can be reduced. As the instantaneous light emission intensity can be decreased, particularly the withstand voltage of a drive IC and the like constituting the data driver 2 can also be set low, contributing to a reduction in cost.

Further, with the above-described structure, the data driver 2 can be constituted by one drive IC (made into one chip) while a function similar to the dual scan drive already described is maintained, and therefore the module cost can be reduced drastically. Moreover, since the data driver 2 can be constituted by one drive IC while the function similar to the dual scan drive is maintained, in a case where a large-sized display screen is to be achieved by further bonding display panels as described later in detail, extent of being restricted by arrangement and structure of data drivers can be reduced.

In the dual scan drive already described, variations in respective drive current values are easy to occur accompanied by variations in two drive ICs sandwiching a display area. Influenced by these variations, although a conventional structure has a problem that a large intensity difference occurs at approximately the center of the display area, with the structure shown in FIG. 3, this intensity difference can be prevented from occurring effectively. With the structure shown in FIG. 3, as cathode line scanning, adjacent cathode lines need not necessarily be simultaneously scanned, and by simultaneously scanning cathode lines which are distanced apart from each other in the display panel, the above-described operations and effects can be obtained.

In the embodiment shown in FIG. 3, control is performed so that timings of selective scanning for cathode lines corresponding to an odd number and an even number are synchronous with each other and that selecting times therefor are the same. According to this embodiment, however, control can be performed also so that selective scanning times for cathode lines corresponding to an odd number and an even number are different from each other.

Next, FIG. 4 schematically shows a lamination state of respective functional layers constituting the display panel 1 shown in FIG. 3. Basically films of respective functional layers described later are formed for example on a transparent glass substrate to form the display panel 1. First, the anode lines A1, A2, . . . as data lines are formed on the substrate in the vertical direction utilizing a photolithographic method and the like. As these anode lines, well-known ITO is employed, and together with these anode lines of the vertical direction, a film of the same ITO is formed as an anode electrode on an area on which the subpixels Ra11, Rb11, . . . constituted by EL elements respectively are formed.

With this structure, on adjacent anode lines which are paired as described above, for example, on the anode lines A1, A2, films of ITO are formed in a state in which areas on which the subpixels Ra11, Rb11, . . . are formed are alternately formed making comb-like shapes. This is also similarly constructed for example on the paired anode lines A3, A4 and the paired anode lines A5, A6.

Then, although not shown in the drawing, a film of insulating layer which is made of for example high molecular polyimide and the like is formed on an entire surface except the area on which the subpixels Ra11, Rb11, . . . are formed. After this, scan line separation partitions 22 are formed in the form of stripes in a direction perpendicular to the anode lines A1, A2, . . . . After these scan line separation partitions 22 are formed, films of organic EL materials are formed for example by resistance heating deposition method. At this time, the films of organic EL materials are formed over the entire surface including areas where subpixels by the above-mentioned ITO are formed.

Metal thin films by aluminum material or the like constituting cathode lines are formed for example by resistance heating deposition method. Although the metal thin films are formed over the entire surface, the metal thin films are electrically separated in the direction of the thickness of the surface by the existence of the scan line separation partitions 22 formed in the form of stripes. As a result, the metal thin films function as the cathode side electrodes of the subpixels Ra11, Rb11, . . . formed by film formation of organic EL materials and are formed as the cathode lines K1, K2, . . . mutually electrically insulated by the scan line separation partitions 22.

In a self light emission display device according to the present invention, in the above-described structure, each of subpixels Ra11, Rb11, . . . is formed into a rectangular shape and has approximately the same area. Respective subpixels formed corresponding to the paired adjacent anode lines have a structure in which the subpixels are mutually arranged in a zigzag pattern.

FIGS. 5 to 8 show respective structures which utilize the self light emission display device described above. The structure shown in FIG. 5 shows a structure corresponding to FIG. 3 already described, and the example shown in this FIG. 5 shows a display panel 1 in which 120 pixels are formed on one scan line, which is arranged 160 lines. Data line pulling electrodes 1a are drawn from one side of a display area which is perpendicular to the longitudinal direction of the data lines in the display panel 1, and these electrodes are connected to the data driver 2 so that lighting drive current is supplied from the data driver 2. Scan line pulling electrodes 1k are drawn from one side of the display area which is perpendicular to the longitudinal direction of the scan lines in the display panel 1, and these electrodes are connected to the scan driver 3 so as to receive selective scanning operation by the scan driver 3.

In the structure shown in FIG. 5, as described with reference to FIG. 3, the scan driver 3 operates so that any two of scan lines arranged in the display panel 1, for example, any one of odd-numbered lines and any one of even-numbered lines, are simultaneously selected for scanning always. Accordingly, as a result of sequential selective scanning for respective scan lines of odd numbers and even numbers, one frame period can be of 80 scans. As a result, the operations and effects described with reference to FIG. 3 can be obtained.

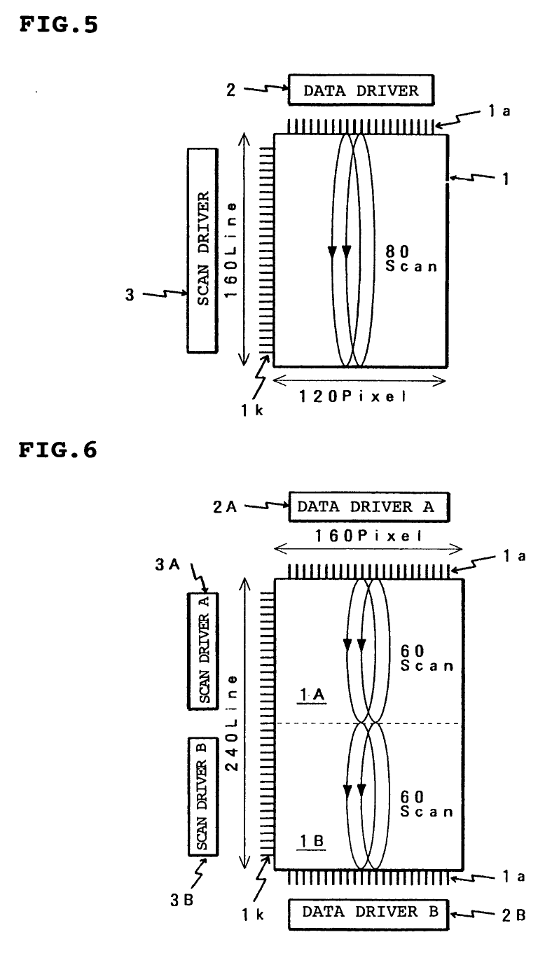

Next, the structure shown in FIG. 6 shows a first example of a case where a display screen is large-sized while the basic structure shown in FIG. 5 is utilized. In the structure shown in this FIG. 6, one display device is formed by mutually bonding other sides of the display area from which the data line pulling electrodes 1a are not drawn in the structure shown in FIG. 5. In this display device, as one example, 160 pixels are formed on one scan line, which is arranged 240 lines.

An upper side display panel 1A is driven by a data driver A designated by reference character 2A and a scan driver A designated by reference character 3A. Further, at the same time, a lower side display panel 1B is driven by a data driver B designated by reference character 2B and a scan driver B designated by reference character 3B. With this structure, in the upper and lower side display panels 1A, 1B, by simultaneously selecting and scanning two scan lines, one frame period can be of 60 scans. Accordingly, even in the case where the display screen is large-sized as shown in FIG. 6, the operations and effects obtained in the structure of FIG. 5 already described can be produced as they are.

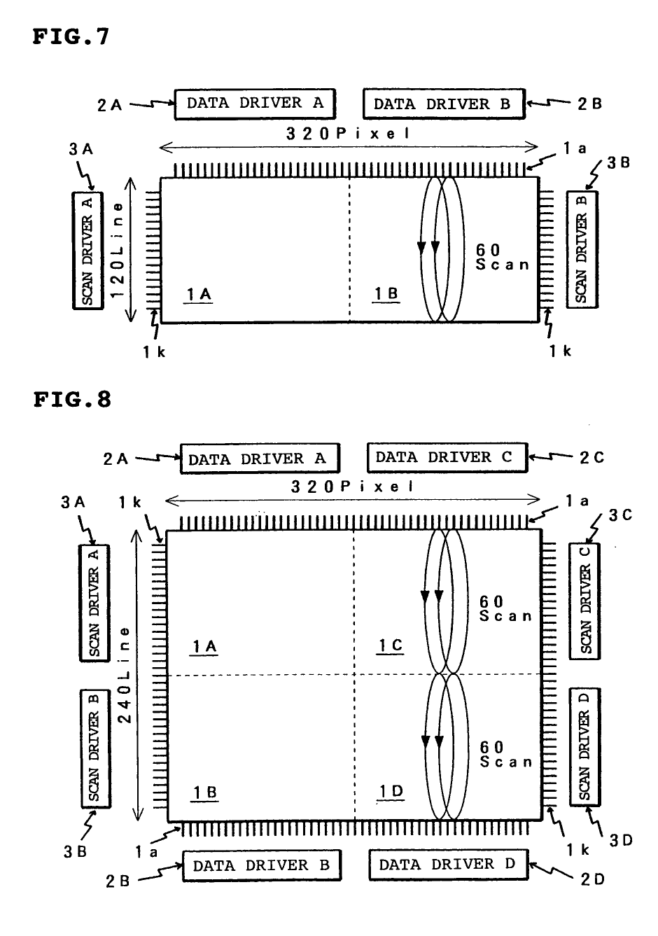

Next, the structure shown in FIG. 7 shows a second example of a case where a display screen is large-sized while the basic structure shown in FIG. 5 is utilized. In the structure shown in this FIG. 7, one display device is formed by mutually bonding other sides of the display area from which the scan line pulling electrodes 1k are not drawn in the structure shown in FIG. 5. In this display device, as one example, 320 pixels are formed on one scan line, which is arranged 120 lines.

A left side display panel 1A is driven by a data driver A designated by reference character 2A and a scan driver A designated by reference character 3A. Further, at the same time, a right side display panel 1B is driven by a data driver B designated by reference character 2B and a scan driver B designated by reference character 3B. With this structure, in the left and right side display panels 1A, 1B, by simultaneously selecting and scanning two scan lines, one frame period can be of 60 scans. Accordingly, even in the case where the display screen is large-sized as shown in FIG. 7, the operations and effects obtained in the structure of FIG. 5 already described can be produced as they are.

The structure shown in FIG. 8 shows a third example of a case where a display screen is further large-sized while the basic structure shown in FIG. 5 is utilized. In the structure shown in this FIG. 8, one display device is formed by mutually bonding other sides of the display area from which the data line pulling electrodes 1a are not drawn and also by mutually bonding other sides of the display area from which the scan line pulling electrodes 1k are not drawn in the structure shown in FIG. 5. In this display device, as one example, 320 pixels are formed on one scan line, which is arranged 240 lines.

An upper left display panel 1A is driven by a data driver A designated by reference character 2A and a scan driver A designated by reference character 3A, and a lower left display panel 1B is driven by a data driver B designated by reference character 2B and a scan driver B designated by reference character 3B. Similarly, an upper right display panel 1C is driven by a data driver C designated by reference character 2C and a scan driver C designated by reference character 3C, and further a lower right display panel 1D is driven by a data driver D designated by reference character 2D and a scan driver D designated by reference character 3D.

In the respective display panels 1A, 1B, 1C, 1D in this structure, by simultaneously selecting and scanning two scan lines, one frame period can be of 60 scans. Accordingly, even in the case where the display screen is large-sized as shown in FIG. 8, the operations and effects obtained in the structure of FIG. 5 already described can be produced as they are.

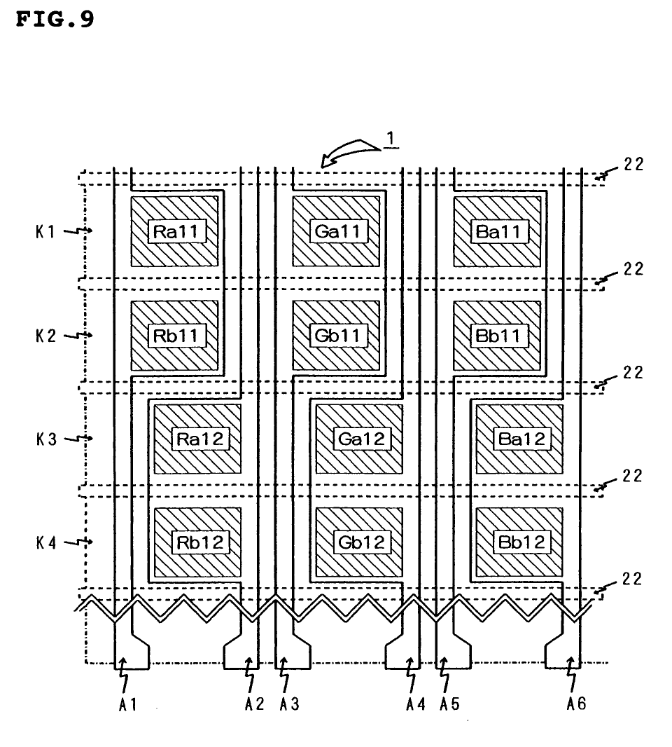

FIG. 9 shows another example of a display panel which can be adopted suitably in a display device according to the present invention, and this schematically shows an arrangement state of respective pixels constituting a display panel 1, similarly to FIG. 4 which is already described. In FIG. 9, parts corresponding to the respective parts shown in FIG. 4 are designated by the same reference characters, and therefore detailed explanation thereof will be omitted suitably. The embodiment shown in this FIG. 9 also is constructed in such a manner that while two adjacent data lines are paired, respective one terminals of the light emitting elements are connected to the paired data lines, respectively, and the other terminals thereof are connected to different scan lines, respectively, one by one.

That is, in a case where attention is paid to the paired, two adjacent data lines A1, A2, respective anode terminals of the EL elements Ra11, Rb11 which emit light of red color are connected to the anode line A1, and respective cathode terminals thereof are connected to different cathode lines K1, K2. Respective anode terminals of the EL elements Ra12, Rb12 which emit light of red color are connected to the anode line A2, and respective cathode terminals thereof are connected to different cathode lines K3, K4. Although not shown further in FIG. 9 due to space, this arrangement and structure for subpixels is similarly produced on the two anode lines A1, A2.

Further, this is also similar on the paired, two adjacent anode lines A3, A4, and on these anode lines A3, A4, respective EL elements Ga11, Ga12, . . . which respectively emit light of green color are formed. Moreover, this is also similar on the paired, two adjacent anode lines A5, A6, and on these anode lines A5, A6, respective EL elements Ba11, Ba12, . . . which respectively emit light of blue color are formed.

In the display panel 1 of the structure shown in FIG. 9 also, any two of the cathode lines are simultaneously selected for scanning. Accordingly, light emission duty of the EL element can be substantially doubled, and operations and effects which are similar to those of the display device in which the display panel of the structure shown in FIG. 4 is employed can be obtained. The arrangement and structure of anode lines as data lines shown in FIG. 9 can be suitably adopted in a display device in which a display screen is to be large-sized as shown in FIGS. 6 to 8 since respective anode lines can be drawn on one side end portion of the display panel 1.

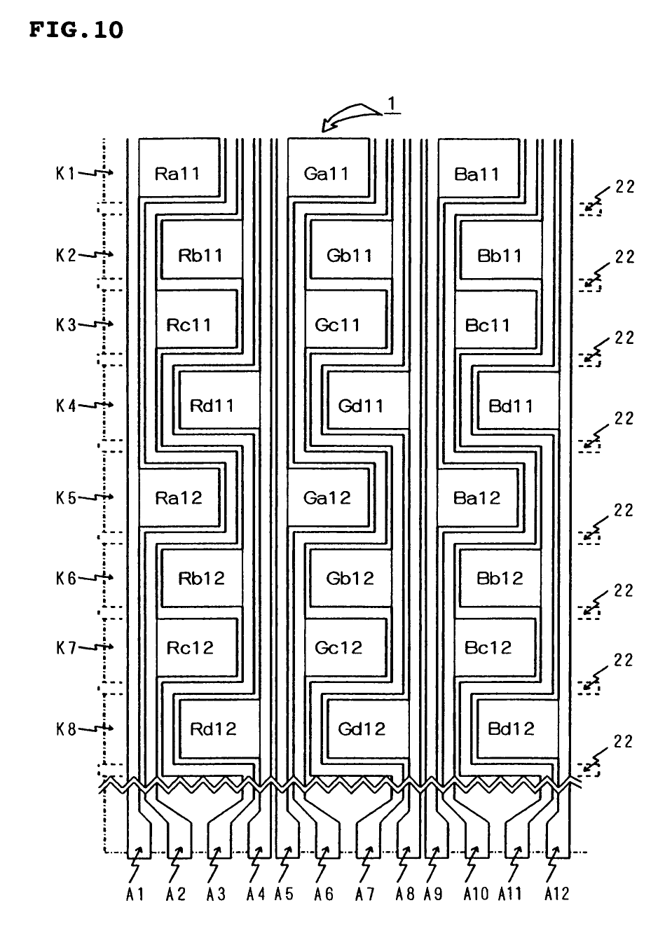

FIG. 10 further shows another example of a display panel which can be suitably adopted in a display device according to the present invention, and this schematically shows an arrangement state of respective pixels constituting a display panel 1, similarly to FIG. 4 which is already described. In FIG. 10, parts corresponding to the respective parts shown in FIG. 4 are designated by the same reference characters, and therefore detailed explanation thereof will be omitted. In FIG. 10, with respect to the scan line separation partitions 22 already described, only portions of left and right positions thereof are shown since avoiding complication in the drawing is intended.

In the embodiment shown in this FIG. 10, four adjacent anode lines are grouped. For example, anode lines A1, A2, A3, A4 are grouped, anode terminals of EL elements Ra11, Rc11, Rb11, Rd11 of red color light emission are respectively connected to these anode lines, and cathode terminals of these EL elements are respectively connected to different cathode lines K1, K3, K2, K4 one by one. Connection pattern of EL elements Ra12, Rc12, Rb12, Rd12 of red color light emission is similar.

Regarding grouped, four adjacent anode lines A5, A6, A7, A8 also, EL elements Ga11, Gb11, . . . of green color light emission are connected following a similar pattern. Further, regarding grouped, four adjacent anode lines A9, A10, A11, A12 also, EL elements Ba11, Bb11, . . . of blue color light emission are connected following a similar pattern.

In the display panel 1 of the structure shown in FIG. 10 also, any two of the cathode lines are simultaneously selected for scanning. Accordingly, light emission duty of the EL element can be substantially doubled, and operations and effects which are similar to those of the display device in which the display panel of the structure shown in FIG. 4 is employed can be obtained. The arrangement and structure of anode lines as data lines shown in FIG. 10 also can be suitably adopted in a display device in which a display screen is to be large-sized as shown in FIGS. 6 to 8 since respective anode lines can be drawn on one side end portion of the display panel 1.

1. A self light emission display device having a plurality of scan lines arranged in one direction, a plurality of data lines arranged as intersecting the scan lines, and a plurality of light emitting elements arranged on intersecting areas of the scan lines and the data lines, characterized by being constructed in such a manner that while adjacent plural data lines are grouped, respective one terminals of the light emitting elements whose respective other terminals are connected to the grouped respective data lines are connected to different scan lines one by one so that any two of the scan lines are simultaneously selected for scanning.

2. The self light emission display device according to claim 1, characterized in that selective scanning timings of any two of the scan lines are synchronous each other and that selecting times therefor are the same.

3. The self light emission display device according to claim 1, characterized by being constructed in such a manner that the light emitting elements whose respective other terminals are connected to respective data lines which are grouped emit the same color.

4. The self light emission display device according to claim 2, characterized by being constructed in such a manner that the light emitting elements whose respective other terminals are connected to respective data lines which are grouped emit the same color.

5. The self light emission display device as set forth in any one of claims 1 to 4, characterized in that areas of light emitting regions of the light emitting elements whose respective other terminals are connected to respective data lines which are grouped are the same.

6. The self light emission display device as set forth in any one of claims 1 to 4, characterized in that the respective light emitting elements whose respective one terminals are connected to the respective scan lines are electrically insulated for each scan line by means of a scan line separation partition.

7. The self light emission display device according to claim 5, characterized in that the respective light emitting elements whose respective one terminals are connected to the respective scan lines are electrically insulated for each scan line by means of a scan line separation partition.

8. The self light emission display device as set forth in any one of claims 1 to 4, characterized in that data line pulling electrodes drawn from a display region of the display device to supply drive current to the respective data lines are drawn from only one side of the display region which is perpendicular to the longitudinal direction of the arranged data lines.

9. The self light emission display device according to claim 5, characterized in that data line pulling electrodes drawn from a display region of the display device to supply drive current to the respective data lines are drawn from only one side of the display region which is perpendicular to the longitudinal direction of the arranged data lines.

10. The self light emission display device according to claim 8, characterized in that other sides of the display regions from which the data line pulling electrodes are not drawn are mutually bonded to construct one display device.

11. The self light emission display device according to claim 9, characterized in that other sides of the display regions from which the data line pulling electrodes are not drawn are mutually bonded to construct one display device.

12. The self light emission display device as set forth in any one of claims 1 to 4, characterized in that scan line pulling electrodes drawn from a display region of the display device to select the respective scan lines for scanning are drawn from only one side of the display region which is perpendicular to the longitudinal direction of the arranged scan lines.

13. The self light emission display device according to claim 5, characterized in that scan line pulling electrodes drawn from a display region of the display device to select the respective scan lines for scanning are drawn from only one side of the display region which is perpendicular to the longitudinal direction of the arranged scan lines.

14. The self light emission display device according to claim 6, characterized in that scan line pulling electrodes drawn from a display region of the display device to select the respective scan lines for scanning are drawn from only one side of the display region which is perpendicular to the longitudinal direction of the arranged scan lines.

15. The self light emission display device according to claim 12, characterized in that other sides of the display regions from which the scan line pulling electrodes are not drawn are mutually bonded to construct one display device.

16. The self light emission display device according to claim 13, characterized in that other sides of the display regions from which the scan line pulling electrodes are not drawn are mutually bonded to construct one display device.

17. The self light emission display device according to claim 14, characterized in that other sides of the display regions from which the scan line pulling electrodes are not drawn are mutually bonded to construct one display device.

18. The self light emission display device as set forth in any one of claims 1 to 4, characterized by comprising four display devices of structures in which data line pulling electrodes drawn from a display region of the display device to supply drive current to the respective data lines are drawn from only one side of the display region which is perpendicular to the longitudinal direction of the arranged data lines and in which scan line pulling electrodes drawn from a display region of the display device to select the respective scan lines for scanning are drawn from only one side of the display region which is perpendicular to the longitudinal direction of the arranged scan lines, and characterized in that other sides of the display regions from which the data line pulling electrodes are not drawn are mutually bonded and other sides of the display regions from which the scan line pulling electrodes are not drawn are mutually bonded to construct one display device.

19. The self light emission display device according to claim 5, characterized by comprising four display devices of structures in which data line pulling electrodes drawn from a display region of the display device to supply drive current to the respective data lines are drawn from only one side of the display region which is perpendicular to the longitudinal direction of the arranged data lines and in which scan line pulling electrodes drawn from a display region of the display device to select the respective scan lines for scanning are drawn from only one side of the display region which is perpendicular to the longitudinal direction of the arranged scan lines, and characterized in that other sides of the display regions from which the data line pulling electrodes are not drawn are mutually bonded and other sides of the display regions from which the scan line pulling electrodes are not drawn are mutually bonded to construct one display device.

20. The self light emission display device as set forth in any one of claims 1 to 4, characterized in that the light emitting element is an organic EL element in which an organic compound is employed in a light emitting layer.
